(19) United States
(12) Patent Application Publication
(10) Pub. No.: US 2022/0260916 A1
(43) Pub. Date: Aug. 18, 2022

(54) DUAL DEVELOPING METHOD FOR DEFINING DIFFERENT RESIST PATTERNS

(71) Applicant: NANYA TECHNOLOGY CORPORATION, New Taipei City (TW)

(72) Inventors: Yung-Chuan YEH, TAOYUAN CITY (TW); Jen-Ho CHEN, TAOYUAN CITY (TW)

(21) Appl. No.: 17/178,969

(22) Filed: Feb. 18, 2021

(51) Int. Cl. G03F 7/213; H01L 21/027; G03F 7/16; G03F 7/039; G03F 7/038; G03F 7/38

(52) U.S. Cl. CPC G03F 7/213; H01L 21/0274; G03F 7/38; G03F 7/039; G03F 7/038; G03F 7/16

(57) ABSTRACT

The present disclosure provides a dual developing method for defining different resist patterns. In the present disclosure, by using a positive-tone development (PTD) process followed by a negative-tone development (NTD) process, and by allowing a first pattern to be transparent under a subsequent second photomask, different patterns can be formed on a same resist layer. As a result, problems encountered in prior art, such as insufficient DOF, formation of abnormal patterns, self-alignment issue, overlying problem and other problems, can be successfully addressed.

### TECHNICAL FIELD

The present disclosure relates to a method for preparing a semiconductor device, and more particularly, to a method for preparing a semiconductor device using a dual developing method for defining different resist patterns.

### DISCUSSION OF THE BACKGROUND

Fabrication of an integrated circuit (IC) involves processes that can generally be categorized as deposition, patterning, and doping. With the use of these processes, complex structures having various components may be built to form the complex circuitry of a semiconductor device.

Lithography is extensively utilized in IC manufacturing, where various IC patterns are transferred to a substrate to form a semiconductor device. A lithography process may involve forming a resist layer on a substrate, exposing the resist layer to radiation, and developing the exposed resist layer, thereby forming a patterned resist layer.

In lithography (or “photolithography”), a radiation-sensitive (“photosensitive”) layer is formed over one or more layers which are to be treated in some manner, such as to be selectively doped and/or have a pattern transferred thereto. A resist layer is itself first patterned by exposing it to radiation, where the radiation (selectively) passes through an intervening photomask or reticle containing the pattern. As a result, exposed or unexposed areas of the resist layer become more or less soluble, depending on a type of the resist layer used. A developer is then used to remove the more soluble areas of the resist layer, leaving a patterned photoresist. The patterned photoresist can then serve as a photomask for underlying layers, which can then be selectively treated, such as to undergo etching, for example.

Lithography may use one of two types of developing processes: a positive-tone development (PTD) process and a negative-tone development (NTD) process. The PTD process uses a positive-tone developer, which refers to a developer that selectively dissolves and removes exposed portions of a resist layer. The NTD process uses a negative-tone developer, which refers to a developer that selectively dissolves and removes unexposed portions of the resist layer. The PTD process uses aqueous-based developers and aqueous-based rinse solutions. The NTD process uses organic-based developers and organic-based rinse solutions. Both PTD processes and NTD processes have drawbacks when attempting to meet lithography resolution demands for advanced technology nodes. For example, both PTD processes and NTD processes have been observed to cause resist pattern swelling, leading to insufficient contrast between exposed portions and unexposed portions of the resist layer (in other words, poor resist contrast) and resulting in deformation, collapse, and/or peeling problems. In PTD processes, aqueous-based rinse solutions are prone to protonize the carboxyl group of the resist layer, thereby producing residues of the resist layer. Also, current PTD and NTD processes lead to various resist-layer structural issues.

As IC structures continue to be scaled down, conventional patterning processes for PTD and NTD photoresists suffer from poor depth of focus, defectivity, and reduced overlay performance. Additionally, openings created during patterning of PTD and NTD photoresists after the photoresists are developed can include non-uniform critical dimensions.

Accordingly, although existing lithography techniques have been generally adequate for their intended purposes, they have not been entirely satisfactory in all respects.

This Discussion of the Background section is provided for background information only. The statements in this Discussion of the Background are not an admission that the subject matter disclosed in this section constitutes prior art with respect to the present disclosure, and no part of this Discussion of the Background section may be used as an admission that any part of this application, including this Discussion of the Background section, constitutes prior art with respect to the present disclosure.

### SUMMARY

The present disclosure is directed to a dual developing method for defining different resist patterns, which can be generally characterized as comprising the following steps: providing a substrate including a peripheral region and an array region adjacent to the peripheral region; forming a resist layer on the substrate using a dual-tone photoresist; exposing the resist layer to radiation through a first photomask to define a first pattern in the peripheral region; developing the resist layer using a positive-tone developer to form a first pattern in the peripheral region and a remaining unexposed portion of the resist layer in the array region; exposing the first pattern in the peripheral region and the resist layer in the array region to radiation through a second photomask to define a second pattern; and developing the resist layer in the array region using a negative-tone developer to form a second pattern in the array region, wherein the first pattern and the second pattern are different, and wherein the first pattern is substantially light-transmittable under the second photomask.

In some embodiments, the method further comprises pre-treating the substrate by dehydration and baking for reducing or eliminating moisture on a surface of the substrate.

In some embodiments, the method further comprises applying a compound selected from the group consisting of hexa-methyl-disilazane (HMDS), tri-methyl-silyl-diethyl-amine (TMSDEA), and combinations thereof to a surface of the substrate.

In some embodiments, the substrate is a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a III-V compound semiconductor, or a combination thereof.

In some embodiments, the step of forming a resist layer on the substrate is carried out by spin coating the dual-tone photoresist onto the substrate.

In some embodiments, the dual-tone photoresist is a photoresist that can be used to produce either positive-tone or negative-tone relief patterns depending on a choice of development solvent used.

In some embodiments, the dual-tone photoresist comprises a photoresist SAIL-Z187©.

In some embodiments, the method further comprises soft-baking the resist layer prior to the step of developing the resist layer using a positive-tone developer.

In some embodiments, the positive-tone developer is an aqueous solution of tetra-methyl ammonium hydroxide.

In some embodiments, the negative-tone developer is an organic solution of n-butyl acetate (n-BA).

In some embodiments, the method further comprises performing a post-exposure baking step of the substrate after the step of exposing the resist layer to radiation through a first photomask to define a first pattern in the peripheral region.

In some embodiments, the method further comprises performing a post-exposure baking step of the substrate after the step of exposing the first pattern in the peripheral region and the resist layer in the array region to radiation through a second photomask to define a second pattern.

In the present disclosure, by using a PTD process followed by an NTD process and by allowing the first pattern 204 to be substantially light-transmittable under the second photomask 601, different patterns can be formed on a same resist layer. In addition, problems encountered in prior art, such as insufficient DOF, formation of abnormal patterns, self-alignment issue, overlying problem, and so on, can be successfully addressed.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a representative flow diagram of a dual developing method 10 for defining different patterns on a same resist layer according to an embodiment of the present disclosure.

FIG. 2 is an illustrative perspective view showing the substrate 201 according to an embodiment of the present disclosure after the performing of step S101 in FIG. 1.

FIG. 3 is an illustrative perspective view showing the substrate 201 according to an embodiment of the present disclosure after the performing of step S102 in FIG. 1.

FIG. 4 is an illustrative perspective view showing the substrate 201 according to an embodiment of the present disclosure after the performing of step S103 in FIG. 1.

FIG. 4A is an illustrative top view showing the substrate 201 in FIG. 4.

FIG. 4B is a schematic cross-sectional view, taken along line A-A in FIG. 4A, of the substrate 201 according to an embodiment of the present disclosure after the performing of step S103 in FIG. 1.

FIG. 5 is an illustrative perspective view showing the substrate 201 according to an embodiment of the present disclosure after the performing of step S104 in FIG. 1.

FIG. 5A is an illustrative perspective view showing the substrate 201 according to an embodiment of the present disclosure after the performing of step S104 in FIG. 1.

FIG. 5B is an illustrative top view showing the substrate 201 in FIG. 5A.

FIG. 5C is a schematic cross-sectional view, taken along line B-B in FIG. 5B, of the substrate 201 according to an embodiment of the present disclosure after the performing of step S104 in FIG. 1.

FIG. 6 is an illustrative perspective view showing the substrate 201 according to an embodiment of the present disclosure after the performing of step S105 in FIG. 1.

FIG. 6A is an illustrative top view showing the substrate 201 in FIG. 6.

FIG. 6B is a schematic cross-sectional view, taken along line C-C in FIG. 6A, of the substrate 201 according to an embodiment of the present disclosure after the performing of step S105 in FIG. 1.

FIG. 7 is an illustrative perspective view showing the substrate 201 according to an embodiment of the present disclosure after the performing of step S106 in FIG. 1.

FIG. 7A is an illustrative perspective view showing the substrate 201 according to an embodiment of the present disclosure after the performing of step S106 in FIG. 1.

FIG. 7B is an illustrative top view showing the substrate 201 in FIG. 7A.

FIG. 7C is a schematic cross-sectional view, taken along line D-D in FIG. 7B, of the substrate 201 according to an embodiment of the present disclosure after the performing of step S106 in FIG. 1.

### DETAILED DESCRIPTION

For the sake of brevity, conventional techniques related to semiconductor device and integrated circuit (IC) fabrication may or is may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Embodiments (or examples) of the disclosure illustrated in the drawings are now described using specific language. It shall be understood that no limitation to the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence is or addition of one or more other features, integers, steps, operations, elements, components, or groups thereof.

As used herein, the terms “patterning” and “patterned” are used in the present disclosure to describe an operation of forming a predetermined pattern on a surface. The patterning operation includes various steps and processes, and varies in accordance with different embodiments. In some embodiments, a patterning process is adopted to pattern an existing film or layer. The patterning process includes forming a mask on the existing film or layer and removing an unmasked portion of the film or layer with an etching or other removal process. The mask can be a photoresist or a hard mask. In some embodiments, a patterning process is adopted to form a patterned layer directly on a surface. The patterning process includes forming a photosensitive film on the surface, conducting a photolithography process, and performing a developing process. After the developing process, a remaining portion of the photosensitive film is retained and integrated into the semiconductor device.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The present disclosure will be described in detail with reference to the accompanying drawings with numbered elements. It is should be noted that the drawings are in greatly simplified form and are not drawn to scale. Moreover, dimensions have been exaggerated in order to provide a clear illustration and understanding of the present invention.

The dual developing method for defining different patterns on a same resist layer of the present disclosure will be explained in detail below along with drawings.

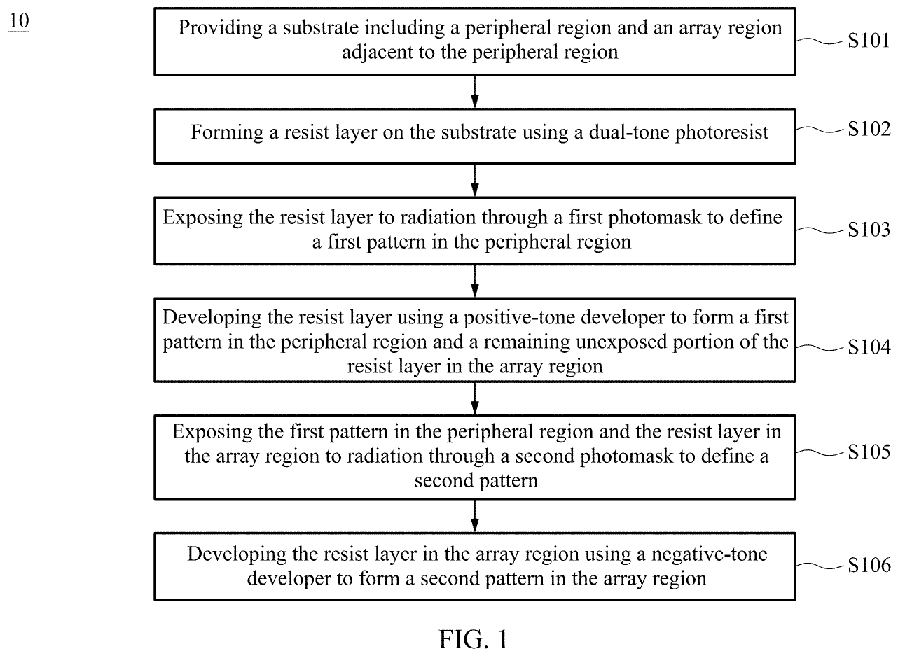

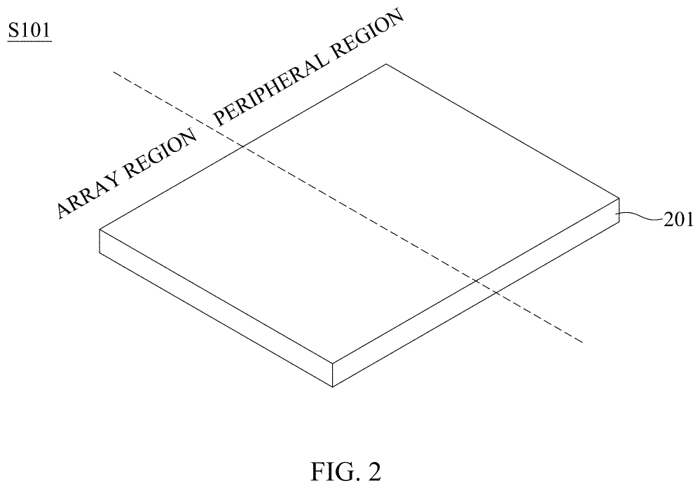

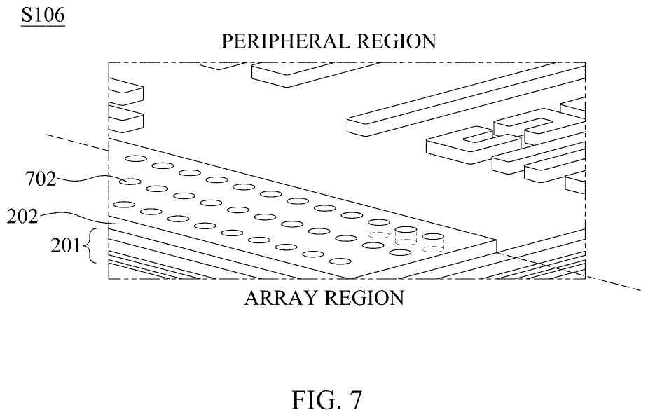

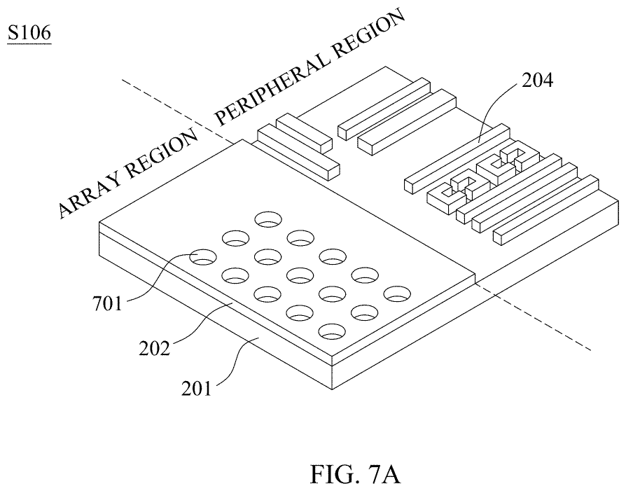

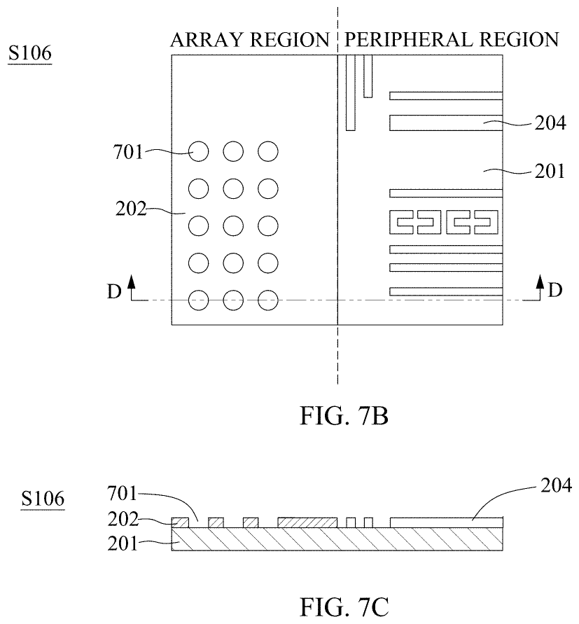

FIG. 1 is a representative flow diagram of a dual developing method 10 for defining different patterns on a same resist layer according to an embodiment of the present disclosure. FIGS. 2, 3, 4, 4A, 4B, 5, 5A, 5B, 5C, 6, 6A, 6B, 7, 7A, 7B, and 7C are illustrative perspective views, top views or schematic cross-sectional views showing a semiconductor device after steps of the method are performed in accordance with some embodiments of the present disclosure.

Before step S101 in FIG. 1 is performed, a substrate 201 can optionally be pre-treated by dehydration and baking so as to reduce or eliminate moisture on a surface of the substrate 201. In addition, in order to improve adhesion of a resist layer 202 on the surface of the substrate 201, compounds such as hexa-methyl-disilazane (HMDS) and tri-methyl-silyl-diethyl-amine (TMSDEA) can be applied to the surface of the substrate 201.

Referring to FIG. 1, in step S101, the substrate 201 including a peripheral region and an array region adjacent to the peripheral region is provided. In the present disclosure, the term “substrate” means and includes a base material or construction upon which materials are formed. It will be appreciated that the substrate may include a single is material, a plurality of layers of different materials, a layer or layers having regions of different materials or different structures in them, or another similar arrangement. These materials may include semiconductors, insulators, conductors, or combinations thereof. For example, the substrate 201 may be a semiconductor substrate, a base semiconductor layer on a supporting structure, a metal electrode, or a semiconductor substrate having one or more layers, structures or regions formed thereon. The substrate 201 may be a conventional silicon substrate or other bulk substrate including a layer of semiconductive material. In some embodiments, the substrate 201 may be a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a III-V compound semiconductor, a combination thereof, or the like.

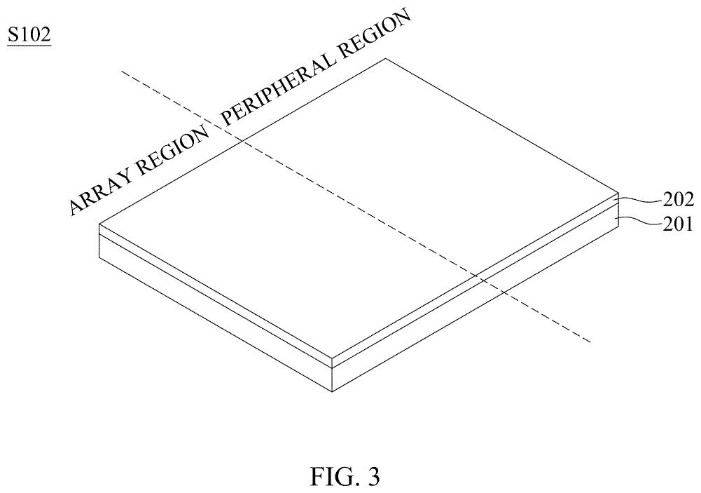

Referring to FIGS. 1 and 3, in step S102, a resist layer 202 is formed on the substrate 201 using a dual-tone photoresist. In one exemplary process, the dual-tone photoresist is applied to the substrate 201, and the substrate 201 is then spun on a turntable at a high speed to produce a resist layer having a desired thickness. This process is known as spin coating. Without intending to be bound by theory, the thickness of the dual-tone photoresist is inversely proportional to a square root of the spin speed and is directly proportional to a viscosity of the dual-tone photoresist. Thus, greater spin speeds lead to a thinner resist layer while a more viscous photoresist material leads to a thicker resist layer.

The term “dual-tone photoresist” refers to a photoresist which can be used to produce either positive-tone or negative-tone relief patterns depending on a choice of development solvent used. Typically, a single development step is used to produce a negative-tone or positive-tone film from a dual-tone resist; this single-step process is a standard lithographic procedure used in semiconductor manufacturing.

A dual-tone resist can also be used in alternative “dual-tone development” processes in a sidewall-based double-patterning procedure. In this type of dual-tone development, a first development step uses PTD to remove high exposure dose areas and a subsequent development step uses NTD to remove unexposed or least-exposed dose areas. Dual-tone development of the resist film leaves the intermediate dose areas defining the two features edges intact. Within the context of the present invention, dual-tone development is carried out with two different organic solvents, a PTD organic solvent and an NTD organic solvent. A PTD resist is a type of photoresist in which a portion of the photoresist that is exposed to light becomes soluble to a photoresist developer, while the unexposed portion of the photoresist remains insoluble to the photoresist developer. An NTD resist is a type of photoresist in which a portion of the photoresist that is exposed to light becomes insoluble to the photoresist developer, while the unexposed portion of the photoresist is dissolved by the photoresist developer.

The terms “positive-tone development” and “PTD,” which are used interchangeably throughout the present disclosure, refer to a method by which exposure of a photoresist to a light source, typically followed by post-exposure bake, changes a composition of the photoresist such that exposed portions of the photoresist become more soluble in a positive-tone developing solvent. When the photoresist is developed with this solvent, exposed portions of the photoresist are washed away, leaving a positive-tone relief pattern in the resist film. Within a context of the present invention, the PTD solvent is an organic solvent. The terms “negative-tone development” and “NTD,” which are used interchangeably throughout the present disclosure, refer to a lithography method by which exposure of the photoresist to a light source, typically followed by post-exposure bake, changes the composition of the photoresist, making it more difficult to dissolve in an NTD solvent. When the photoresist is developed, only unexposed portions of the photoresist wash away, leaving a negative-tone relief pattern etched in the resist. Within the context of the present invention, the NTD solvent is an organic solvent. The NTD organic solvent is selected from a group consisting of a methyl amyl ketone (MAK), n-butyl acetate (nBA), n-pentylacetate (nPA), ethyl amyl ketone (EAK), and combinations thereof.

Any commercially-available dual-tone photoresists can be used in step S102 of the present disclosure. Preferably, the dual-tone photoresist is a photoresist of the SAIL series sold by ShinEtsu Company in Japan. Most preferably, the dual-tone photoresist comprises a photoresist SAIL-Z187© sold by ShinEtsu Company in Japan.

In some embodiments, the dual-tone photoresist according to the present disclosure include a polymer resin along with one or more photoactive compounds (PACs) in a solvent. Optionally, additives such as a cross-linking agent, a coupling agent, a solvent, a quencher, a stabilizer, a dissolution inhibitor, a plasticizer, a coloring agent, an adhesion additive, and a surface leveling agent, and so on can be added to the photoresist.

A resulting resist layer usually contains a certain amount of solvent, for example, between 20 wt. % and 40 wt. %. A so-called soft-baking or pre-baking process, can be used to remove this excess solvent. A main reason for reducing the solvent content is to stabilize the resulting resist layer. At room temperature, an unbaked resist layer will lose solvent by evaporation, thus changing properties of the resist layer over time. By baking the resist layer, a majority of the solvent is removed and the resist layer becomes stable at room temperature. There are four major effects of removing solvent from the resist layer: (1) thickness is reduced, (2) post-exposure bake and development properties are changed, (3) adhesion is improved, and (4) the photoresist layer becomes less tacky and thus less susceptible to particulate contamination. Typical pre-bake processes leave between 3 wt. % and 8 wt. % residual solvent in the resulting resist layer, sufficiently low to keep the resulting resist layer stable during subsequent lithographic processing.

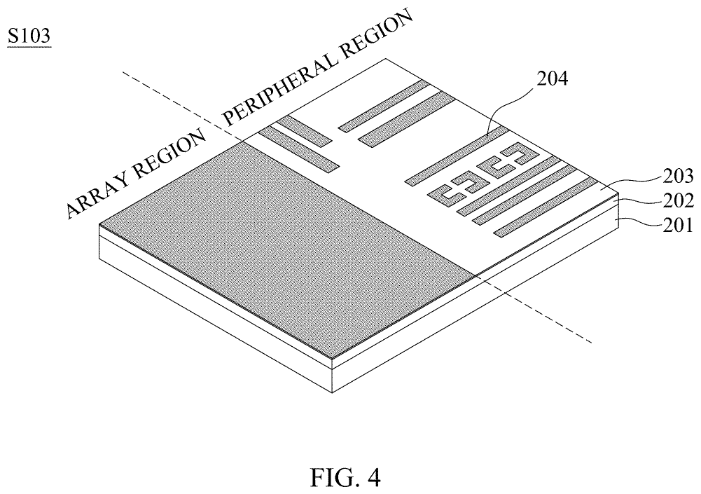

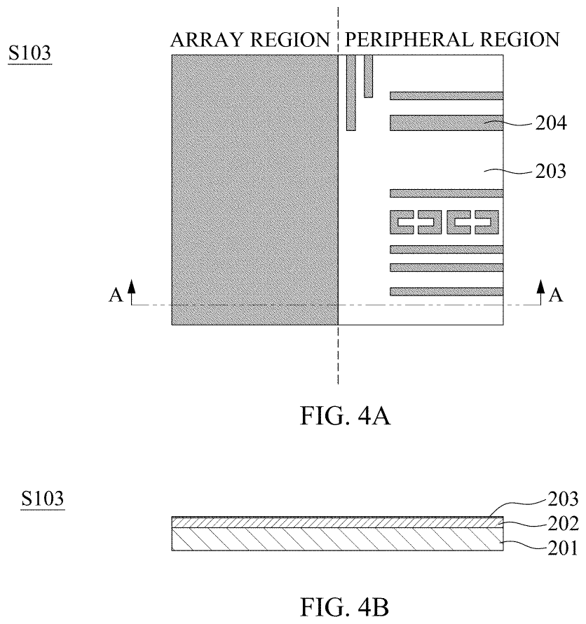

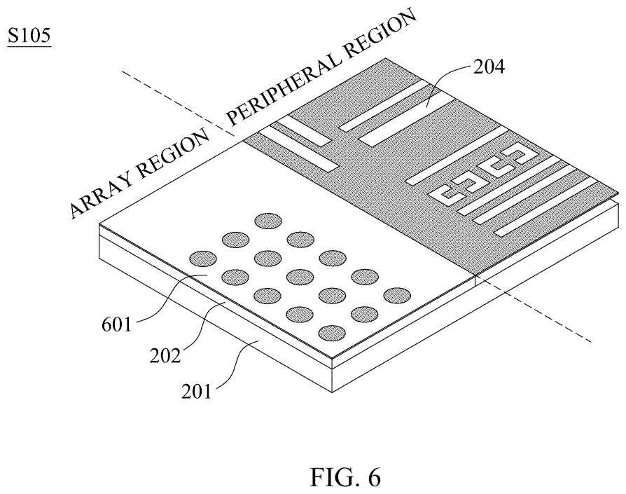

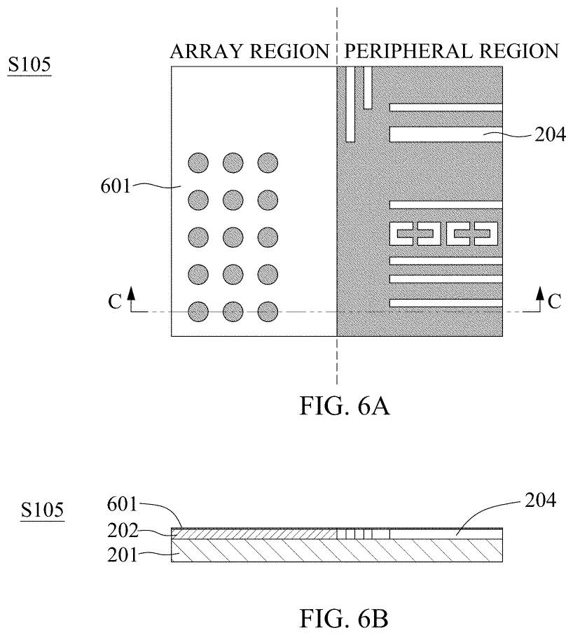

Referring to FIGS. 1, 4, 4A, and 4B, in step S103, the resist layer 202 is exposed to radiation such as deep ultraviolet (DUV) light through a first photomask 203. The first photomask 203 is used to define a first pattern 204 in the peripheral region, wherein the first pattern 204 is substantially light-transmittable under a subsequent photomask (i.e., the second photomask 601 in FIG. 6) so that the first pattern 204 will not be changed during a subsequent NTD process. Optionally, after the preforming of step S103, the substrate 201 is subjected to a post-exposure baking step to improve the stability of the first pattern 204 on the substrate 201.

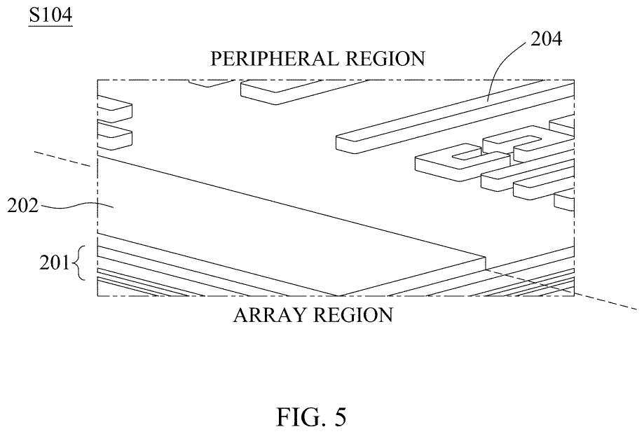

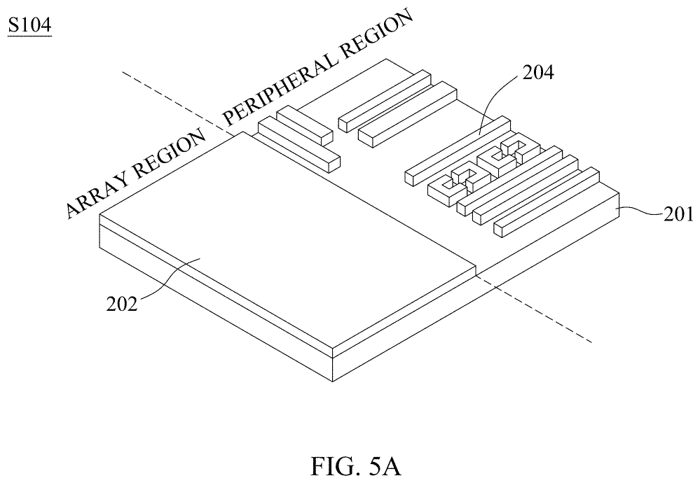

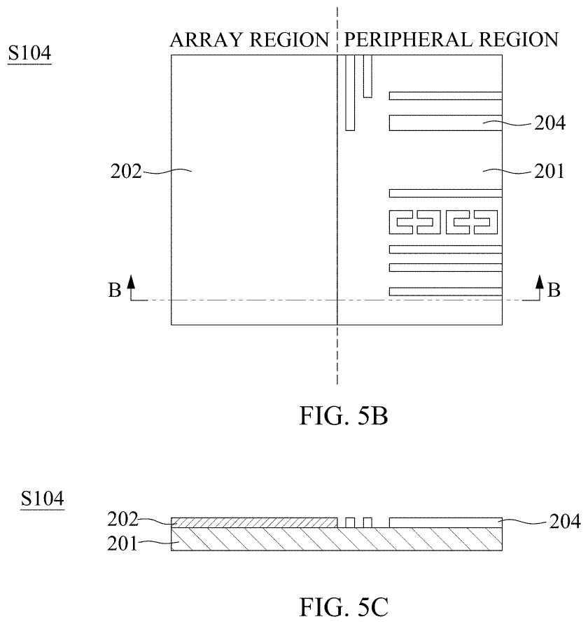

Referring to FIGS. 1, 5, 5A, 5B, and 5C, in step S104, the resist layer 202 is developed using a positive-tone developer so as to form a first pattern 204 in the peripheral region and a remaining unexposed portion of the resist layer 202 in the array region. Positive-tone developers are typically aqueous base developers, such as tetraalkylammonium hydroxide (TMAH). In non-limiting examples, an aqueous solution of TMAH having a concertation of 2.38 wt. %) may be used as the positive-tone developer.

Referring to FIGS. 1, 6, 6A, and 6B, in step S105, the first pattern 204 in the peripheral region and the resist layer 202 in the array region are exposed to radiation such as deep ultraviolet (DUV) light through a second mask 601. In step S105, the resist layer 202 is developed using a negative-tone developer to form a second pattern 701 in the array region. In certain embodiments of the present disclosure, the negative-tone developer may be an organic solvent that is selected to solvate the unexposed portion of the photoresist while not solvating the exposed portion of the photoresist. NTD developers are typically organic-based developers. In non-limiting examples, an organic solution of n-butyl acetate (n-BA) is used as the negative-tone developer.

Optionally, after the preforming of step S105, the substrate 201 is subjected to a post-exposure baking step to improve the stability of the second pattern 701.

Conventional double-patterning methods require the alignment of at least two separate masks. Hence, overlay problems may result. Self-aligned double-patterning methods are typically good for forming semiconductor devices having a one-dimensional structure. However, they become more limited in forming semiconductor devices defined by differences in two dimensions or even three dimensions. In addition, exposing different patterns requires different exposing conditions to achieve a desired depth of field (DOF). Attempting to form different patterns on a same resist layer usually results in insufficient DOF, which causes abnormality of patterns. For example, exposing conditions for forming a line pattern are not suitable for forming a whole pattern, and vice versa. Also, developing conditions will influence patterning ability.

In the present disclosure, by using PTD followed by NTD and by allowing the first pattern 204 to be substantially light-transmittable to be transparent under the second mask 601, different patterns can be formed on a same resist layer. Also, problems encountered in prior art, such as insufficient DOF, formation of abnormal patterns, self-alignment issue, overlying problem and other problems, can be successfully addressed.

It should be understood that the preceding examples are included to demonstrate specific embodiments of the present disclosure. It should be appreciated by those having skill in the art that the techniques disclosed in the examples which follow represent techniques discovered by the inventors to function well in the practice of the present disclosure, and thus can be considered to constitute preferred modes for its practice. However, it should be understood that the present disclosure is not intended to be limited to the particular forms disclosed. Rather, the different aspects of the disclosed process may be utilized in various combinations and/or independently. Thus, the present disclosure is not limited to only those combinations shown herein, but rather may include other combinations. Further, those having skill in the art should, in light of the present disclosure, appreciate that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A dual developing method for defining different resist patterns, comprising:
providing a substrate including a peripheral region and an array region adjacent to the peripheral region;
forming a resist layer on the substrate using a dual-tone resist;
exposing the resist layer to radiation through a first photomask to define a first pattern in the peripheral region;
developing the resist layer using a positive-tone developer to form a first pattern in the peripheral region and a remaining unexposed portion of the resist layer in the array region;
exposing the first pattern in the peripheral region and the resist layer in the array region to radiation through a second photomask to define a second pattern; and
developing the resist layer in the array region using a negative-tone developer to form a second pattern in the array region;
wherein the first pattern and the second pattern are different, and wherein the first pattern is substantially light-transmittable under the second photomask.

2. The method according to claim 1, further comprising: pre-treating the substrate by dehydration and baking for reducing or eliminating moisture on a surface of the substrate.

3. The method according to claim 1, further comprising: applying a compound selected from a group consisting of hexa-methyl-disilazane (HMDS), tri-methyl-silyl-diethyl-amine (TMSDEA), and combinations thereof to a surface of the substrate.

4. The method according to claim 1, wherein the substrate is a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a III-V compound semiconductor, or a combination thereof.

5. The method according to claim 1, wherein the step of forming a resist layer on the substrate is carried out by spin coating the dual-tone photoresist onto the substrate.

6. The method according to claim 1, wherein the dual-tone photoresist includes a photoresist which can be used to produce either positive-tone or negative-tone relief patterns depending on the choice of development solvent used.

7. The method according to claim 1, wherein the dual-tone photoresist includes a photoresist SAIL-Z187©.

8. The method according to claim 1, further comprising: soft-baking the resist layer prior to the step of developing the resist layer using a positive-tone developer to form a first pattern.

9. The method according to claim 1, wherein the positive-tone developer includes an aqueous solution of tetra-methyl ammonium hydroxide.

10. The method according to claim 1, wherein the negative-tone developer includes an organic solution of n-butyl acetate (n-BA).

11. The method according to claim 1, further comprising: preforming a post-exposure baking step of the substrate after the step of exposing the resist layer to radiation through a first photomask to define a first pattern in the peripheral region.

12. The method according to claim 1, further comprising: preforming a post-exposure baking step of the substrate after the step of exposing the first pattern in the peripheral region and the resist layer in the array region to radiation through a second photomask.
